(19) United States
(12) Patent Application Publication
(10) Pub. No.: US 2022/0153030 A1
(43) Pub. Date: May 19, 2022

(54) HEAD MAINTENANCE UNIT AND APPARATUS FOR TREATING SUBSTRATE

(71) Applicant: SEMES CO., LTD., Chungcheongnam-do (KR)

(72) Inventors: Byung Joo LEE, Daegu (KR); Sang Hwa LEE, Chungcheongnam-do (KR); Dong Yun LEE, Chungcheongnam-do (KR); Jee Yong JUNG, Chungcheongnam-do (KR); Hahn Seok JEON, Chungcheongnam-do (KR); Kang KWON, Chungcheongnam-do (KR); Jae Hun JEONG, Chungcheongnam-do (KR); Sang Hoon KIM, Incheon (KR)

(21) Appl. No.: 17/529,323

(22) Filed: Nov. 18, 2021

(30) Foreign Application Priority Data
Nov. 19, 2020 (KR) 10-2020-0155336

(51) Int. Cl. B41J 2/165

(52) U.S. Cl. CPC B41J 2/16552; B41J 2002/16555

(57) ABSTRACT

The present invention provides an apparatus for treating a substrate, the apparatus including: a head unit including a head formed with one or more nozzles that discharge a treatment liquid to a substrate; and a head maintenance unit configured to perform maintenance for the head, in which the head maintenance unit may include: a liquid receiving block formed with one or more liquid receiving parts having liquid receiving spaces with open tops; a decompression line fluidly-communicating with the liquid receiving space and configured to provide reduced pressure to the liquid receiving space; and a decompression valve installed in the decompression line.

### CROSS-REFERENCE TO RELATED APPLICATIONS

This application claims priority to and the benefit of the Korean Patent Application No. 10-2020-0155336 filed in the Korean Intellectual Property Office on Nov. 19, 2020, the entire contents of which are incorporated herein by reference.

### TECHNICAL FIELD

The present invention relates to a head maintenance unit and an apparatus for treating a substrate.

### BACKGROUND ART

Recently, display devices, such as liquid crystal display devices and organic EL display devices, are required to have high resolution. In order to manufacture a display device having high resolution, it is necessary to form more pixels per unit area on a substrate, and it is important to accurately discharge a chemical solution, such as ink, to each of pixels that are densely arranged as described above. This is because, if not, the display device manufactured as defective may be determined to be defective. Accordingly, according to the related technologies, it is required to accurately manage a discharge point (for example, a hitting point) of the chemical solution discharged to each of the pixels and the amount of discharge of the chemical solution in manufacturing the display device. Accordingly, in order to obtain data for the hitting point of the chemical solution and the amount of discharge of the chemical solution when a head discharging ink discharges the chemical solution or minimize the occurrence of clogging in a nozzle due to the solidification of the chemical solution in the nozzle formed in the head, the head of a general inkjet device performs pre-jetting.

FIG. 1 is a diagram illustrating a state where a head of a general inkjet device performs pre-jetting. Referring to FIG. 1, a general inkjet device 1 includes a head unit 2. The head unit 2 includes a plurality of heads 4 discharging ink droplets I, a head frame 3 to which the plurality of heads 4 is fitted, and a head interface board 5 which controls the head 4. Further, the inkjet device 1 includes a head maintenance member 6. The head maintenance member 6 includes a porous plate 8 absorbing the ink I in the form of droplets discharged by the head 4 and a support frame 7 supporting the porous plate 8. The porous plate 8 and the support frame 7 are provided in plurality.

As described above, in order to check whether the discharge point of the ink I discharged by the head 4 and the amount of discharge of the ink I are accurately managed (or in order to prevent a clogging phenomenon of the nozzle formed in the head 4), the head 4 performs pre-jetting before treating a substrate. The pre-jetting is performed in the state where the heads 4 are positioned between the porous plates 8. Optionally, the pre-jetting may also be performed in the state where the heads 4 are positioned above the porous plates 8.

As described above, in order to accurately discharge the ink I to each of the densely arranged pixels, the volume of ink I discharged by the head 4 is gradually decreased recently. The volume of ink I in the form of droplets discharged by the head 4 may be 6 pico liter (PL) or less. As the volume of ink I in the form of droplets discharged by the head 4 is decreased as described above, the ink I discharged when the head 4 performs the pre-jetting may be scattered. The scattered ink I may contaminate a substrate treating apparatus 1 in which the head interface board 5 and/or the head unit 2 are installed.

### SUMMARY OF THE INVENTION

The present invention has been made in an effort to provide a head maintenance unit and an apparatus for treating a substrate which are capable of effectively performing maintenance for a head.

The present invention has also been made in an effort to provide a head maintenance unit and an apparatus for treating a substrate which are capable of minimizing contamination of an apparatus for treating a substrate by ink in the form of droplets discharged from a head when the head performs pre-jetting.

The present invention has also been made in an effort to provide a head maintenance unit and an apparatus for treating a substrate which are capable of minimizing scattering of ink in the form of droplets discharged from a head when the head performs pre-jetting.

The problem to be solved by the present invention is not limited to the above-mentioned problems, and the problems not mentioned will be clearly understood by those skilled in the art from the present specification and the accompanying drawings.

An exemplary embodiment of the present invention provides an apparatus for treating a substrate, the apparatus including: a head unit including a head formed with one or more nozzles that discharge a treatment liquid to a substrate; and a head maintenance unit configured to perform maintenance for the head, wherein the head maintenance unit includes: a liquid receiving block formed with one or more liquid receiving parts having liquid receiving spaces with open tops; a decompression line fluidly-communicating with the liquid receiving space and configured to provide reduced pressure to the liquid receiving space; and a decompression valve installed in the decompression line.

In the exemplary embodiment, the liquid receiving block may include a decompression flow path which is connected with the decompression line, and fluidly-communicates with the liquid receiving space.

In the exemplary embodiment, the liquid receiving block may further include a connection flow path formed between the decompression flow path and the liquid receiving space.

In the exemplary embodiment, in the connection flow path, a connection valve for selectively fluidly-communicating the decompression flow path and the liquid receiving space may be installed.

In the exemplary embodiment, the head may be provided in plurality, and the liquid receiving parts may be provided in the same number as the number of heads provided.

In the exemplary embodiment, the head and the liquid receiving part may be provided in plurality, and the liquid receiving parts may be formed in the liquid receiving block in a direction in which the heads are arranged.

In the exemplary embodiment, the apparatus may further include a control unit, in which the control unit may perform any one of a purging operation of purging the head by supplying gas to a pipe connected with the head, and a pre-jetting operation of discharging the treatment liquid to the maintenance unit in the form of droplets.

In the exemplary embodiment, when the control unit performs the pre-jetting operation, the control unit may control the head unit and the head maintenance unit so that the liquid receiving block is located under the head and the decompression valve is turned on when the head discharges the treatment liquid in the form of droplets.

In the exemplary embodiment, when viewed from above, the liquid receiving part may have: a lateral surface extended in a vertical direction; and an inclined surface extended in a downwardly inclined direction from the lateral surface.

Another exemplary embodiment of the present invention provides a head maintenance unit which is included in an apparatus for treating a substrate by discharging ink and which performs maintenance for a head discharging the ink, the head maintenance unit including: a liquid receiving block including one or more liquid receiving units including a liquid receiving space having an open top; a decompression line which fluidly communicates with the liquid receiving space and provides a reduced pressure to the liquid receiving space; and a decompression valve installed in the decompression line.

In the exemplary embodiment, the liquid receiving block may include a decompression flow path which is connected with the decompression line, and fluidly-communicates with the liquid receiving space.

In the exemplary embodiment, the liquid receiving block may further include a connection flow path formed between the decompression flow path and the liquid receiving space.

In the exemplary embodiment, in the connection flow path, a connection valve for selectively fluidly-communicating the decompression flow path and the liquid receiving space may be installed.

In the exemplary embodiment, the liquid receiving unit may be formed in the liquid receiving block in a direction in which the plurality of heads is arranged.

In the exemplary embodiment, when viewed from above, the liquid receiving part may have: a lateral surface extended in a vertical direction; and an inclined surface extended in a downwardly inclined direction from the lateral surface.

Still another exemplary embodiment of the present invention provides an apparatus for treating a substrate by discharging ink, the apparatus including: a head unit including one or more heads formed with nozzles that discharge ink to a substrate in a form of droplets; a printing region in which the head discharges the ink to the substrate to perform a printing process on the substrate; a maintenance region which is disposed with the printing region side by side when viewed from above and in which maintenance for the head is performed; a gentry provided so that the head unit reciprocates between the printing region and the maintenance region; and a head maintenance unit which is installed in the maintenance region, configured to be movable in a direction parallel to a movement direction of the substrate in the printing region, and performs maintenance on the head, in which the head maintenance unit includes: a liquid receiving block including one or more liquid receiving units including liquid receiving spaces having open tops; a decompression line which fluidly communicates with the liquid receiving space and provides a reduced pressure to the liquid receiving space; and a decompression valve installed in the decompression line.

In the exemplary embodiment, the liquid receiving block may include a decompression flow path which is connected with the decompression line, and fluidly-communicates with the liquid receiving space.

In the exemplary embodiment, when viewed from above, the liquid receiving part may have: a lateral surface extended in a vertical direction; and an inclined surface extended in a downwardly inclined direction from the lateral surface.

In the exemplary embodiment, the apparatus may further include a control unit, in which the control unit performs any one of a purging operation of purging the head by supplying gas to a pipe connected with the head, and a pre-jetting operation of discharging the ink to the maintenance unit in the form of droplets.

In the exemplary embodiment, when the control unit performs the pre-jetting operation, the control unit may control the head unit and the head maintenance unit so that the liquid receiving block is located under the head and the decompression value is turned on when the head discharges the ink in the form of droplets.

According to the exemplary embodiment of the present invention, it is possible to effectively perform maintenance for the head.

Further, according to the exemplary embodiment of the present invention, it is possible to minimize the contamination of the substrate treating apparatus by the ink in the form of droplets discharged from the head when the head performs the pre-jetting.

Furthermore, according to the exemplary embodiment of the present invention, it is possible to minimize the scattering of the ink discharged from the head when the head performs the pre-jetting.

The effect of the present invention is not limited to the foregoing effects, and non-mentioned effects will be clearly understood by those skilled in the art from the present specification and the accompanying drawings.

### BRIEF DESCRIPTION OF THE DRAWINGS

FIG. 1 is a diagram illustrating a state where a head of a general inkjet device performs pre-jetting.

FIG. 2 is a diagram illustrating a substrate treating apparatus according to an exemplary embodiment of the present invention.

FIG. 3 is a diagram illustrating a head maintenance unit of FIG. 2.

FIG. 4 is a diagram illustrating a liquid receiving block and a decompression line connected to the liquid receiving block of FIG. 3.

FIG. 5 is a cross-sectional view of the liquid receiving block and the decompression line of FIG. 4 viewed from B-B′.

FIG. 6 is a cross-sectional view of the liquid receiving block of FIG. 4 viewed from A-A′.

FIG. 7 is a diagram illustrating a suction cleaning module of FIG. 4.

FIG. 8 is a diagram illustrating a state where a head of a substrate treating apparatus performs pre-jetting according to an exemplary embodiment of the present invention.

FIG. 9 is a diagram illustrating a liquid receiving block according to another exemplary embodiment of the present invention.

FIG. 10 is a diagram illustrating a liquid receiving block according to another exemplary embodiment of the present invention.

FIG. 11 is a diagram illustrating a head maintenance unit according to another exemplary embodiment of the present invention.

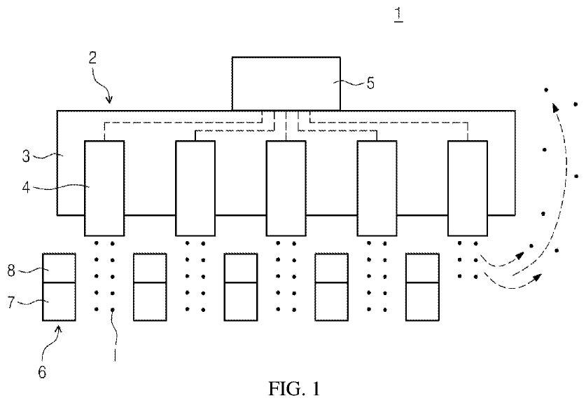

### DETAILED DESCRIPTION

Hereinafter, an exemplary embodiment of the present invention will be described more fully hereinafter with reference to the accompanying drawings, in which exemplary embodiments of the invention are shown. However, the present invention can be variously implemented and is not limited to the following embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” and variations such as “includes” or “including” will be understood to imply the inclusion of stated elements but not the exclusion of any other elements. It will be appreciated that terms “including” and “having” are intended to designate the existence of characteristics, numbers, steps, operations, constituent elements, and components described in the specification or a combination thereof, and do not exclude a possibility of the existence or addition of one or more other characteristics, numbers, steps, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element can be directly coupled to or connected to the other constituent element, but intervening elements may also be present. In contrast, when one constituent element is “directly coupled to” or “directly connected to” another constituent element, it should be understood that there are no intervening element present. Other expressions describing the relationship between the constituent elements, such as “between” and “just between” or “adjacent to ˜”, and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

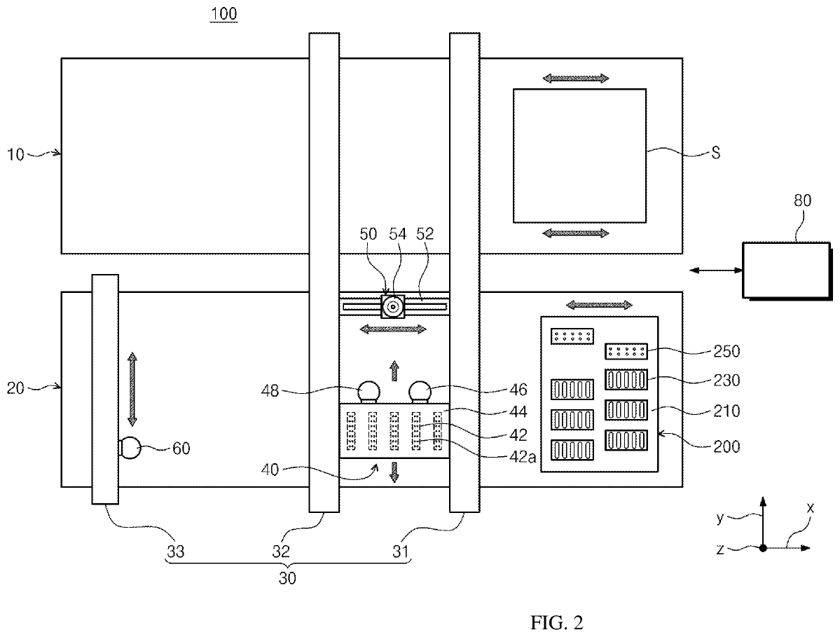

Hereinafter, exemplary embodiments of the present invention will be described with reference to FIGS. 2 to 10.

FIG. 2 is a diagram illustrating a substrate treating apparatus according to an exemplary embodiment of the present invention. Referring to FIG. 2, a substrate treating apparatus 100 according to an exemplary embodiment of the present invention may be an inkjet device which treats a substrate by supplying a chemical liquid, such as ink, onto a substrate S. For example, the substrate treating apparatus 100 may perform a printing process on the substrate S by discharging ink I in the form of droplets onto the substrate S. Further, the substrate S may be a glass substrate. However, the present invention is not limited thereto, and the type of substrate S may be variously changed.

The substrate treating apparatus 100 may include a printing region 10, a maintenance region 20, a gantry 30, a head unit 40, a nozzle align unit 50, a fourth vision unit 60, a control unit 80, and a head maintenance unit 200.

A longitudinal direction of the printing region 10 may be a first direction X when viewed from above. Hereinafter, when viewed from above, a direction perpendicular to the first direction X is referred to as a second direction Y, and a direction perpendicular to the first direction X and the second direction Y is referred to as a third direction Z. The third direction Z may be a direction perpendicular to the ground. Further, the first direction X may be a direction in which the substrate S, which will be described below, is transferred. In the printing region 10, a printing process may be performed on the substrate S by discharging, by the head unit 40, which is to be described below, the ink I in the form of droplets to the substrate S.

Further, in the printing region 10, the transferred substrate S may maintain a floating state. Accordingly, in the printing region 10, a floating stage for floating the substrate S when the substrate S is transferred may be provided. Further, in the printing region 10, a transferring unit which grips one side surface or both side surfaces and transfers the substrate S may be further provided. The transferring unit may include a guide rail provided along one side or both sides of the floating stage, a gripper that slides along the guide rail while griping one side surface or both side surfaces of the substrate S, and the like. Further, in the printing region 10, the transferred substrate, for example, the substrate S, may be transferred in the first direction X.

In the maintenance region 20, maintenance for the head unit 40, which is to be described below, may be mainly performed. When viewed from above, a longitudinal direction of the maintenance region 20 may be the first direction X. Further, the maintenance region 20 and the printing region may be disposed side by side. For example, the maintenance region 20 and the printing region 10 may be arranged side by side in the second direction Y.

Before and after the head unit 40 discharges the treatment liquid I to the substrate S in the form of droplets, a head 42 of the head unit 40, which is to be described below, may discharge the treatment liquid in the maintenance region 20. For example, in the maintenance region 20, at least one of a purging operation and a pre-jetting operation may be performed. The control unit 80, which is to be described below, may control the head unit 40, which is to be described below, so as to perform at least one of the pursing operation and the pre-jetting operation in the maintenance region 20.

The purging operation may supply inert gas, such as nitrogen, to a pipe (not illustrated) connected with the head 42 of the head unit 40, which is to be described below, and purge the pipe connected with the head 42. When the inert gas is supplied to the pipe connected with the head 42, the supplied inert gas may push the treatment liquid I left in the pipe toward a nozzle 42a of the head 42. The treatment liquid I pushed toward the nozzle 42a may be discharged through the nozzle 42a.

Further, the pre-jetting operation may be performed in order to collect a hitting point of the treatment liquid I in the form of droplets discharged by the head 42 of the head unit 40 and data for adjusting the volume of the treatment liquid I. Further, the pre-jetting operation may be performed in order to prevent a clogging phenomenon from occurring in the nozzle 42a due to the solidification of the treatment liquid I in the nozzle 42a formed in the head 42 of the head unit 40. In the pre-jetting operation, the head 42 of the head unit 40 may discharge the treatment liquid I in the form of droplets. In the pre-jetting operation, the head unit 40 may discharge the treatment liquid I to the maintenance region 200 provided in the maintenance region in the form of droplets. In the pre-jetting operation, the volume of treatment liquid I in the form of droplets discharged by the head unit 40 may be 6 pico liter (PL) or less.

Further, since in the maintenance region 20, the head unit 40, which is to be described below, is capable of discharging the treatment liquid I in the form of droplets, the maintenance region 20 may have the process environment that is the same as or similar to the printing region 10.

The gentry 30 may be provided so that the head unit 40, which is to be described below, or the fourth vision unit 60, which is to be described below, may reciprocate in a straight line. The gentry 30 may include a first gentry 31, a second gentry 32, and a third gentry 33. The first gentry 31 and the second gentry 32 may be provided to have a structure extending along the printing region 10 and the maintenance region 20. Further, the first gentry 31 and the second gentry 32 may be disposed while being spaced apart from each other in the first direction X. That is, the first gentry 31 and the second gentry 32 may be provided to have a structure extending in the second direction Y in which the printing region 10 and the maintenance region 20 are disposed so that the head unit 40, which is to be described below, is capable of reciprocating between the printing region 10 and the maintenance region 20 in the second direction Y.

Further, the third gentry 33 may be provided to have a structure extending in the second direction Y. That is, the third gentry 33 may be provided to have a structure extending so that the fourth vision unit 60, which is to be described below, is capable of moving in the second direction Y.

The head unit 40 may discharge the treatment liquid I to the substrate S in the form of droplets. The treatment liquid I discharged by the head unit 40 may be ink. The head unit 40 may perform a printing process on the substrate S by discharging the treatment liquid I to the substrate S in the form of droplets. For example, the head unit 40 may perform the printing process on the substrate S by discharging the treatment liquid I to the substrate S while reciprocating in the second direction Y.

The head unit 40 may include the head 42, a head frame 44, a head interface board 45, a first vision unit 46, and a second vision unit 48.

A plurality of nozzles 42a discharging the treatment liquid I in the form of droplets may be formed in the head 42. One or more heads 42 may be provided. For example, the head 42 may be provided in plurality. The plurality of heads 42 may be arranged side by side in the first direction X. The plurality of heads 42 may be fitted to the head frame 44. Further, a head interface board 45 may be installed in the head frame 44. The head interface board 45 may control the volume of the ink I discharged by head 42 by controlling the head 42.

The head 42 may be movably coupled to the first gentry 31 and the second gentry 32 via the head frame 44. For example, the head 42 may be provided to be movable in the second direction Y that is the longitudinal direction of the first gentry 31 and the second gentry 32. Further, the head 42 may reciprocate in a straight line between the printing region 10 and the maintenance region 20 in the second direction Y that is the longitudinal direction of the first gentry 31 and the second gentry 32. When viewed from above, the first vision unit 46 and the second vision unit 48 may be coupled to one side of the head 42. The first vision unit 46 and the second vision unit 48 may be disposed side by side in the first direction X. The first vision unit 46 and the second vision unit 48 may check the treatment liquid I in the form of droplets discharged by the head 42. The first vision unit 46 and the second vision unit 48 may be cameras including image acquiring modules.

A nozzle align unit 50 may be provided to the maintenance region 20. When viewed from above, the nozzle align unit 50 may be provided between the first gentry 31 and the second gentry 32. Accordingly, the nozzle align unit 50 may check the states of the nozzles 42a formed in the head 42. For example, the nozzle align unit 50 may include a movement rail 52 and a third vision unit 54. A longitudinal direction of the movement rail 52 may be the first direction X. The third vision unit 54 may reciprocate in a straight line in the first direction X that is the longitudinal direction of the movement rail 52. The third vision unit 54 may photograph the nozzles 42a of the head 42 while moving in the longitudinal direction of the movement rail 52.

The fourth vision unit 60 may be installed in the third gentry 33 so as to be movable in the second direction Y that is the longitudinal direction of the third gentry 33. The fourth vision unit 60 may be a camera including an image acquiring module. The fourth vision unit 60 may acquire images of the droplets of the ink I discharged to a second substrate S2 and transmit the acquired image to the control unit 80 which is to be described below. The control unit 80 may calculate data for correcting the hitting point of the ink droplet discharged by the head unit 40, the movement speed of the head 42, and a movement speed of the substrate, and the like by analyzing the image acquired by the fourth vision unit 60.

The head maintenance unit 200 may be installed in the maintenance region 20. The head maintenance unit 200 may be configured to be movable in the maintenance region 20. For example, the head maintenance unit 200 may be configured to be movable in the maintenance region 20 in the first direction X. For example, the head maintenance unit 200 may be configured to be movable in a direction parallel to the movement direction of the substrate S in the printing region 10. The head maintenance unit 200 may perform maintenance on the head 42. A particular structure of the head maintenance unit 200 will be described below.

The control unit 800 may control the substrate treating apparatus 100. The control unit 80 may control the substrate treating apparatus 100 so as for the substrate treating apparatus 100 to perform a treatment process on the substrate S. For example, the control unit 80 may control the substrate treating apparatus 100 so as for the substrate treating apparatus 100 to perform a printing process on the substrate S. Further, the control unit 80 may control the substrate treating apparatus 100 so as for the substrate treating apparatus 100 to perform maintenance for the head unit 40. For example, the control unit 80 may control the head unit 40 and the head maintenance unit 200 so as to perform the maintenance for the head unit 40. Further, the control unit 80 may calculate data for correcting the hitting point of the treatment liquid I in the form of droplets discharged by the head 42 of the head unit 40, the movement speed of the head 42, and a movement speed of the substrate S, and the like based on the images (pictures or videos) captured and acquired by the first vision unit 46, the second vision unit 48, the third vision unit 54, and the fourth vision unit 60.

Further, the control unit 80 may include a process controller formed of a microprocessor (computer) that executes the control of the substrate treating apparatus 100, a user interface formed of a keyboard in which an operator performs a command input operation or the like in order to manage the substrate treating apparatus 100, a display for visualizing and displaying an operation situation of the substrate treating apparatus 100, and the like, and a storage unit storing a control program for executing the process executed in the substrate treating apparatus 100 under the control of the process controller or a program, that is, a treatment recipe, for executing the process in each component according to various data and processing conditions. Further, the user interface and the storage unit may be connected to the process controller. The processing recipe may be stored in a storage medium in the storage unit, and the storage medium may be a hard disk, and may also be a portable disk, such as a CD-ROM or a DVD, or a semiconductor memory, such as a flash memory.

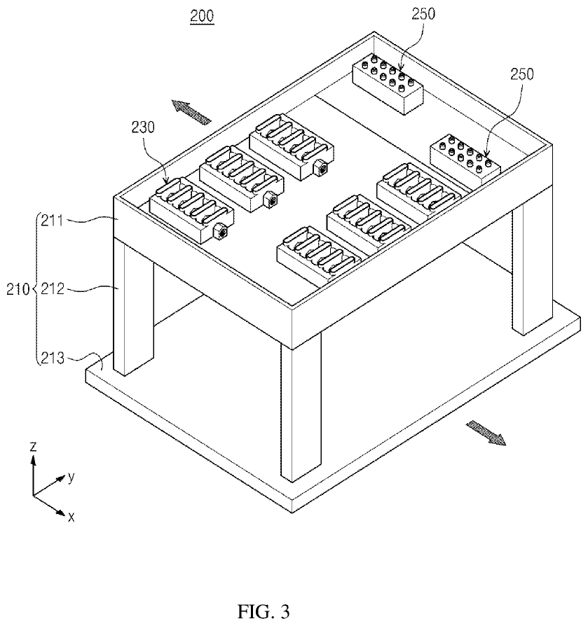

FIG. 3 is a diagram illustrating the head maintenance unit of FIG. 2. Referring to FIG. 3, the head maintenance unit 200 may include a purging bath 210, a liquid receiving block 230, a decompression line 240, a suction cleaning module 250, and a suction line 260. In FIG. 3, for the convenience of the description, the illustration of the decompression line 240 and the suction line 260 is omitted.

The purging bath 210 may be configured to be movable in the maintenance region 20 in the first direction X. The purging bath 210 may be moved to the lower region of the head unit 40 when the purging operation or the pre-jetting operation of the head unit 40 is performed. For example, the purging bath 210 may be configured to be movable in the first direction X by a movement member, such as an LM guide, in the maintenance region 20. Further, the movement member is not limited to the LM guide, and may be variously changed to the publicly known device which is capable of moving the purging bath 210.

The purging bath 210 may include a liquid receiving part 211, a support frame 212, and a support plate 213.

The liquid receiving part 211 may have a cylindrical shape having an open top. The liquid receiving part 211 may have a receiving space for receiving the treatment liquid I discharged from the head 42 when the purging operation or the pre-jetting operation is performed. A discharge line (not illustrated) through which the treatment liquid I supplied to the receiving space of the liquid receiving part 211 is discharged to the outside may be connected to the liquid receiving part 211. Further, the liquid receiving part 211 may be supported by the support plate 213 by the plurality of support frames 212. The support plate 213 may be coupled with the movement member (for example, the LM guide). Accordingly, the purging bath 210 may be moved in the first direction X by the movement member.

Further, the liquid receiving block 230 and the suction cleaning module 250 may be installed in the liquid receiving part 211 of the purging bath 210. At least one liquid receiving block 230 may be installed in the purging bath 210. For example, the plurality of liquid receiving blocks 230 may be installed in the purging bath 210. For example, six liquid receiving blocks 230 may be installed in the purging bath 210. However, the present invention is not limited thereto, and the number of liquid receiving blocks 230 installed in the purging bath 210 may be variously changed. Further, the liquid receiving blocks 230 may be divided into two groups, and the liquid receiving blocks 230 of any one group between the two groups may be arranged in the second direction Y side by side. The liquid receiving blocks 230 of other group between the two groups may be spaced apart from the one group in the first direction X, and may be arranged in the second direction Y side by side. Further, at least one suction cleaning module 250 may be installed in the purging bath 210. For example, the plurality of suction cleaning modules 250 may be installed in the purging bath 210. For example, two suction cleaning modules 250 may be installed in the purging bath 210. However, the present invention is not limited thereto, and the number of suction cleaning modules 250 installed in the purging bath 210 may be variously changed.

The liquid receiving block 230 may be disposed under the head unit 40 in the case where the pre-jetting operation of the head unit 40 is performed. The liquid receiving block 230 may receive the treatment liquid I discharged from the head unit 40 when the head unit 40 discharges the treatment liquid I in the form of droplets. Further, the suction cleaning module 250 may remove the treatment liquids I attached to the nozzle 42a of the head unit 40 or the peripheral region of the nozzle 42a by a vacuum suction method.

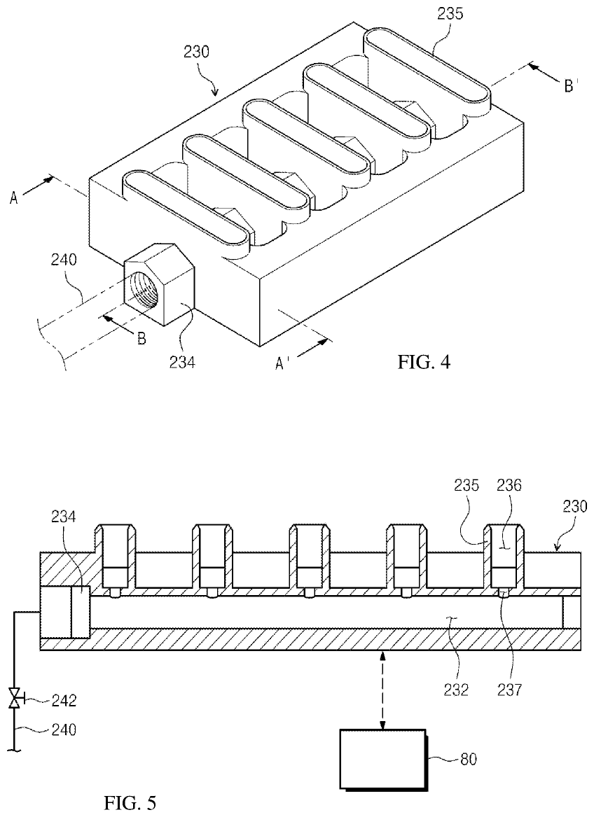

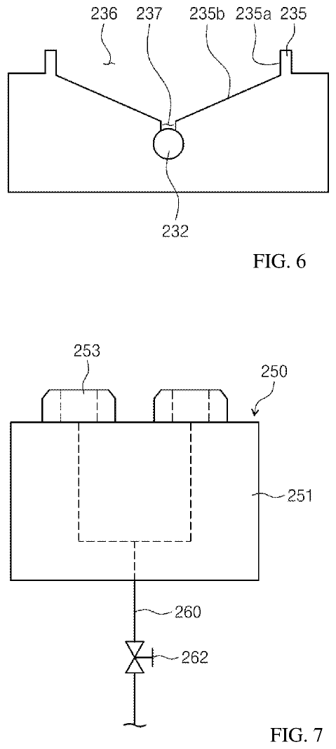

FIG. 4 is a diagram illustrating the liquid receiving block and the decompression line connected to the liquid receiving block of FIG. 3, FIG. 5 is a cross-sectional view of the liquid receiving block and the decompression line of FIG. 4 viewed from B-B′, and FIG. 6 is a cross-sectional view of the liquid receiving block of FIG. 4 viewed from A-A′. Referring to FIGS. 4 to 6, a decompression flow path 232, a coupling port 234, a liquid receiving part 235, and a connection flow path 237 may be formed in the liquid receiving block 230.

The decompression flow path 232 may be formed within the liquid receiving block 230. The decompression flow path 232 may be formed in the longitudinal direction of the liquid receiving block 230 in the liquid receiving block 230. The decompression flow path 232 formed in the liquid receiving block 230 may receive reduced pressure from the decompression line 240 connected through the coupling port 234. A decompression valve 242 may be installed in the decompression line 240. The decompression valve 242 may be an on/off valve, or a flow rate adjusting valve. According to the open/close of the decompression valve 24, the reduced pressure provided by the decompression line 240 may be transmitted to the decompression flow path 232.

The liquid receiving part 235 may be formed above the decompression flow path 232. The liquid receiving part 235 may have a liquid receiving space 236. The liquid receiving space 236 may be provided so as to have an open top. At least one liquid receiving part 235 may be provided. For example, the plurality of liquid receiving parts 235 may be provided. The liquid receiving parts 235 may be provided in the same number as the number of heads 42. The liquid receiving parts 235 may be formed in the liquid receiving block 230 in the direction in which the plurality of heads 42 is arranged. For example, when the heads 42 are arranged in the first direction X, the liquid receiving parts 235 may be formed in the liquid receiving block 230 in the first direction X. Accordingly, in the case where the heads 42 of the head unit 40 are disposed above the liquid receiving block 230 (for example, the pre-jetting is performed), each of the heads 42 may be disposed above each of the liquid receiving parts 235. Accordingly, the pre-jetting for the plurality of heads 42 may be performed at the same time.

When viewed in the longitudinal direction of the liquid receiving block 230, the liquid receiving part 235 may have a lateral surface 235a and an inclined surface 235b. The lateral surface 235a may be extended in the longitudinal direction of the liquid receiving block 230 and in the vertical direction when viewed from the cross-section of the liquid receiving block 230 (chamfer prevention). For example, a stepped portion may not be formed in the lateral surface 235a. Accordingly, when the head 42 discharges the treatment liquid I in the form of droplets which will be described below, the treatment liquid I transmitted to the liquid receiving space 236 flows in the down direction along the lateral surface 235a. That is, it is possible to solve the problem in that the treatment liquid I is attached to the liquid receiving part 235 and accumulated in the liquid receiving part 235. Further, the inclined surface 235b may be extended in a downwardly inclined direction from the lateral surface 235a. The inclined surface 235b may be extended in a downwardly inclined direction toward the connection flow path 237 which is to be described below. The inclined surface 235b may help the treatment liquid I transmitted to the liquid receiving space 236 to be transferred to the decompression flow path 232 via the connection flow path 237.

Further, the connection flow path 237 may be formed between the liquid receiving space 236 and the decompression flow path 232. The connection flow paths 237 may be formed while corresponding to the plurality of liquid receiving parts 235, respectively. The connection flow path 237 may fluidly communicate the decompression flow path 232 and the liquid receiving space 236. Accordingly, the reduced pressure provided by the decompression line 240 may be transferred to the decompression flow path 232, the reduced pressure transferred to the decompression flow path 232 may be transferred to the connection flow path 237, and the reduced pressure transferred to the connection flow path 237 may be transferred to the liquid receiving space 236.

FIG. 7 is a diagram illustrating the suction cleaning module of FIG. 4. Referring to FIG. 7, the suction cleaning module 250 may include a body 251 in which a suction flow path is formed therein, and a suction port 253 for suctioning and cleaning the lower surface of the head 42. Further, the suction cleaning module 250 may be connected with the suction line 260. The suction line 260 may provide reduced pressure to the suction flow path formed in the body 251. Further, the suction valve 262 may be installed in the suction line 260. The suction port 253 suctions the lower surface of the head 42 by the reduced pressure provided by the suction line 260, thereby removing the treatment liquid I attached to the nozzle 42a formed in the head 42 or the peripheral region of the nozzle 42a.

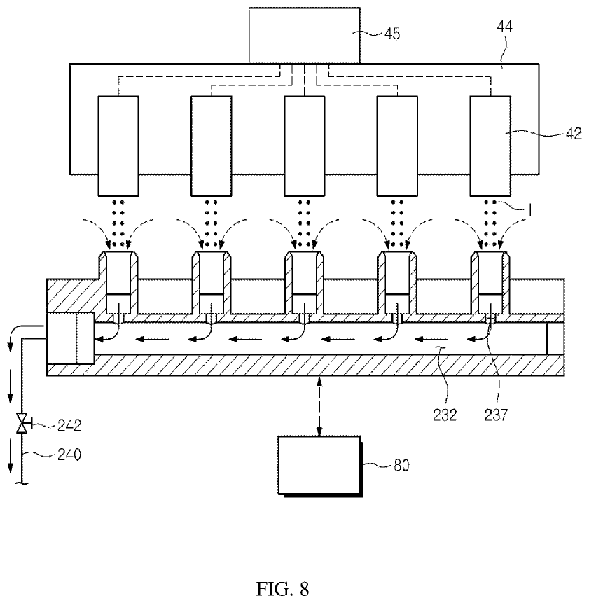

FIG. 8 is a diagram illustrating a state where the head of the substrate treating apparatus performs pre-jetting according to an exemplary embodiment of the present invention. Referring to FIG. 8, when the pre-jetting operation is performed on the head 42, the control unit 80 may control the head unit 40 and the head maintenance unit 200. For example, when the pre-jetting operation is performed, the control unit 80 may move the maintenance unit 200 so that the liquid receiving block 230 is located under the head 42. For example, the control unit 80 may move the head maintenance unit 200 so that the liquid receiving parts 235 of the liquid receiving block 230 are located while corresponding to the lower portions of the plurality of heads 42, respectively. In this case, a gap between an upper end of the liquid receiving part 235 and the lower surface of the head 42 may be 1 mm or less.

Then, the control unit 80 may make the head 42 discharge the treatment liquid I in the form of droplets by controlling the head unit 40. In this case, the volume of treatment liquid I in the form of droplets discharged by the head 42 may be 6 pico liter (PL) or less.

Further, the control unit 80 may control the head maintenance unit 200 so that the decompression valve 242 is turned on before or after the head 42 discharges the treatment liquid I. When the decompression valve 242 is turned on, the reduced pressure provided by the decompression line 240 may be transferred to the liquid receiving space 236 via the decompression flow path 232 and the connection flow path 237. Accordingly, the treatment liquid I in the form of droplets discharged by the head unit 40 may be sucked into the liquid receiving space 236 by the reduced pressure transferred to the liquid receiving space 236. Accordingly, even though the volume of the treatment liquid I discharged in the form of droplets is very small, it is possible to minimize the problem in that the treatment liquid I is scattered. That is, it is possible to minimize the problem in that the treatment liquid I is scattered in the pre-jetting operation, so that it is possible to minimize the substrate treating apparatus 100, for example, the head unit 40, from being contaminated by the scattered treatment liquid I. Accordingly, the risk of contamination of the treated substrate S due to impurities that may be attached to the head unit 40 may be effectively reduced.

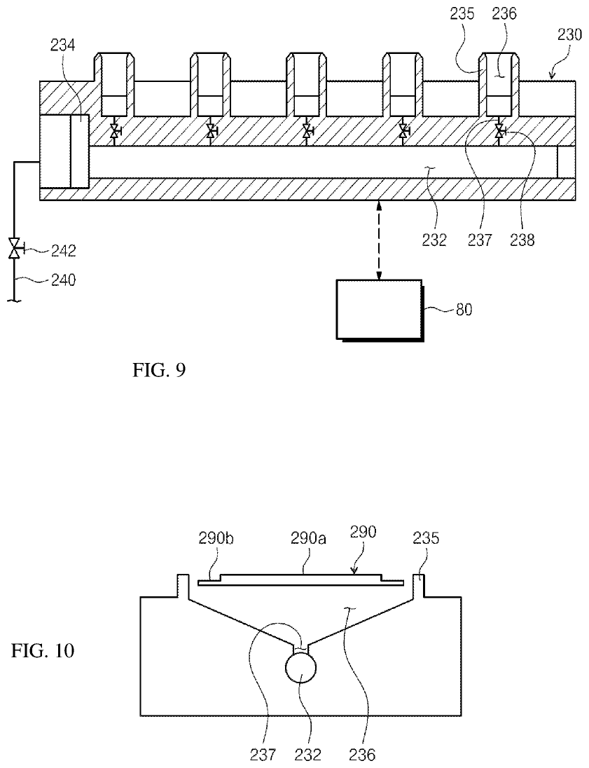

FIG. 9 is a diagram illustrating the liquid receiving block according to another exemplary embodiment of the present invention. Referring to FIG. 9, in each of connection flow paths 237 formed in a liquid receiving block 230 according to another exemplary embodiment, a connection valve 238 which selectively fluidly-communicates a decompression flow path 232 and a liquid receiving space 236 may be installed. The connection valve 238 may be an on/off valve or a flow rate adjusting valve. On/off or an opening/closing rate of the connection valve 238 may be adjusted by the control unit 80. For example, the control unit 80 may set the opening/closing rate of the connection valve 238 adjacent to the decompression line 240 and the opening/closing rate of the connection valve 238 distant from the decompression line 240 to be different from each other. For example, an opening rate of the connection valve 238 adjacent to the decompression line 240 may be smaller than an opening rate of the connection valve 238 distant from the decompression line 240. That is, depending on the connection position of the decompression line 240, the size of reduced pressure transferred to the liquid receiving space 236 of each of the liquid receiving parts 235 may be different. However, according to another exemplary embodiment of the present invention, the size of reduced pressure transferred to the liquid receiving space 236 of each of the liquid receiving parts 235 may be adjusted to be the same by differently adjusting the opening/closing rates of the connection valves 238.

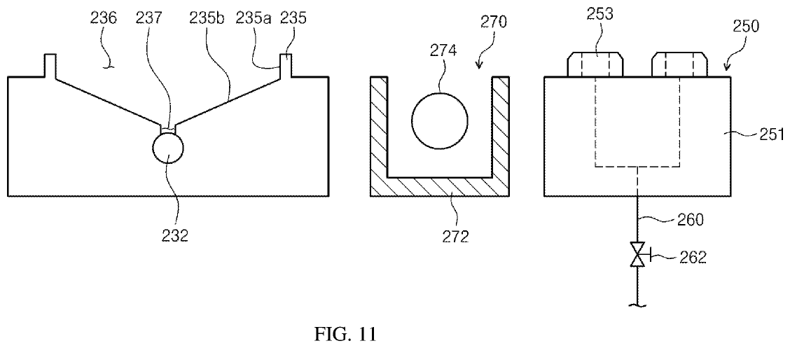

FIG. 10 is a diagram illustrating a liquid receiving block according to another exemplary embodiment of the present invention. Referring to FIG. 10, a liquid receiving member 290 may be installed in a liquid receiving block 230 according to another exemplary embodiment of the present invention. The liquid receiving member 290 may be a porous plate capable of absorbing a treatment liquid I discharged by a head 42. The liquid receiving member 290 may have a stepped shape so that a height of an upper surface 290a in the center region is different from a height of an upper surface 290b in the edge region. For example, the height of the upper surface 290a in the center region of the liquid receiving member 290 may be greater than the height of the upper surface 290b in the edge region. When the liquid receiving member 290 is provided, a phenomenon in which the treatment liquid I is formed may occur in the edge region of the liquid receiving member 290. When the treatment liquid I is formed in the edge region of the liquid receiving member 290, the treatment liquid I may be transferred to the lower surface of the head 42. Accordingly, the height of the upper surface 290b in the edge region of the liquid receiving member 290 is provided to be lower, thereby minimizing the contamination of the head 42 due to the formation of the treatment liquid I. Further, the liquid receiving member 290 is provided in the porous plate, so that the reduced pressure transferred to the liquid receiving space 236 may be transferred to the lower surface of the head 42 through the liquid receiving member 290.

FIG. 11 is a diagram illustrating a head maintenance unit according to another exemplary embodiment of the present invention. Referring to FIG. 11, a head maintenance unit 200 according to another exemplary embodiment of the present invention may further include a head cleaning module 270. The head cleaning module 270 may include a frame 272 and a head cleaning bar 274. The head cleaning bar 274 may clean the treatment liquid I attached to the head 42. The head cleaning bar 274 may be provided to be rotatable. The head cleaning bar 274 may be provided within the frame 272 having an open top.

In the foregoing example, the case where the liquid receiving block 230 is used in the pre-jetting operation of the head unit 40, but the present invention is not limited thereto. For example, the liquid receiving block 230 may be used in various processing operations of discharging, by the head unit 40, the treatment liquid I having a fine volume and the maintenance operation in the same or similar manner.

The foregoing detailed description illustrates the present invention. Further, the above content shows and describes the exemplary embodiment of the present invention, and the present invention can be used in various other combinations, modifications, and environments. That is, the foregoing content may be modified or corrected within the scope of the concept of the invention disclosed in the present specification, the scope equivalent to that of the disclosure, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. An apparatus for treating a substrate, the apparatus comprising:
a head unit including a head formed with one or more nozzles that discharge a treatment liquid to a substrate; and
a head maintenance unit configured to perform maintenance for the head,
wherein the head maintenance unit includes:
a liquid receiving block formed with one or more liquid receiving parts having liquid receiving spaces with open tops;
a decompression line fluidly-communicating with the liquid receiving space and configured to provide reduced pressure to the liquid receiving space; and
a decompression valve installed in the decompression line.

2. The apparatus of claim 1, wherein the liquid receiving block includes a decompression flow path which is connected with the decompression line, and fluidly-communicates with the liquid receiving space.

3. The apparatus of claim 2, wherein the liquid receiving block further includes a connection flow path formed between the decompression flow path and the liquid receiving space.

4. The apparatus of claim 3, wherein in the connection flow path, a connection valve for selectively fluidly-communicating the decompression flow path and the liquid receiving space is installed

5. The apparatus of claim 1, wherein the head is provided in plurality, and
the liquid receiving parts are provided in the same number as the number of heads provided.

6. The apparatus of claim 1, wherein the head and the liquid receiving part are provided in plurality, and
the liquid receiving parts are formed in the liquid receiving block in a direction in which the heads are arranged

7. The apparatus of claim 1, further comprising:
a control unit,
wherein the control unit performs any one of a purging operation of purging the head by supplying gas to a pipe connected with the head, and
a pre-jetting operation of discharging the treatment liquid to the maintenance unit in the form of droplets.

8. The apparatus of claim 7, wherein when the control unit performs the pre-jetting operation, the control unit controls the head unit and the head maintenance unit so that the liquid receiving block is located under the head and the decompression valve is turned on when the head discharges the treatment liquid in the form of droplets.

9. The apparatus of claim 1, wherein when viewed from above, the liquid receiving part has:
a lateral surface extended in a vertical direction; and
an inclined surface extended in a downwardly inclined direction from the lateral surface.

10. A head maintenance unit which is included in an apparatus for treating a substrate by discharging ink and which performs maintenance for a head discharging the ink, the head maintenance unit comprising:
a liquid receiving block including one or more liquid receiving units including a liquid receiving space having an open top;
a decompression line which fluidly communicates with the liquid receiving space and provides a reduced pressure to the liquid receiving space; and
a decompression valve installed in the decompression line.

11. The head maintenance unit of claim 10, wherein the liquid receiving block includes a decompression flow path which is connected with the decompression line, and fluidly-communicates with the liquid receiving space.

12. The head maintenance unit of claim 11, wherein the liquid receiving block further includes a connection flow path formed between the decompression flow path and the liquid receiving space.

13. The head maintenance unit of claim 12, wherein in the connection flow path, a connection valve for selectively fluidly-communicating the decompression flow path and the liquid receiving space is installed.

14. The head maintenance unit of claim 10, wherein the liquid receiving unit is formed in the liquid receiving block in a direction in which the plurality of heads is arranged.

15. The head maintenance unit of claim 10, wherein when viewed from above, the liquid receiving part has: a lateral surface extended in a vertical direction; and
an inclined surface extended in a downwardly inclined direction from the lateral surface.

16. An apparatus for treating a substrate by discharging ink, the apparatus comprising:
a head unit including one or more heads formed with nozzles that discharge ink to a substrate in a form of droplets;
a printing region in which the head discharges the ink to the substrate to perform a printing process on the substrate;
a maintenance region which is disposed with the printing region side by side when viewed from above and in which maintenance for the head is performed;
a gentry provided so that the head unit reciprocates between the printing region and the maintenance region; and
a head maintenance unit which is installed in the maintenance region, configured to be movable in a direction parallel to a movement direction of the substrate in the printing region, and performs maintenance on the head,
wherein the head maintenance unit includes:
a liquid receiving block including one or more liquid receiving units including liquid receiving spaces having open tops;
a decompression line which fluidly communicates with the liquid receiving space and provides a reduced pressure to the liquid receiving space; and
a decompression valve installed in the decompression line.

17. The apparatus of claim 16, wherein the liquid receiving block includes a decompression flow path which is connected with the decompression line, and fluidly-communicates with the liquid receiving space.

18. The apparatus of claim 16, wherein when viewed from above, the liquid receiving part has: a lateral surface extended in a vertical direction; and
an inclined surface extended in a downwardly inclined direction from the lateral surface.

19. The apparatus of claim 16, further comprising:
a control unit,
wherein the control unit performs any one of a purging operation of purging the head by supplying gas to a pipe connected with the head, and
a pre-jetting operation of discharging the ink to the maintenance unit in the form of droplets.

20. The apparatus of claim 19, wherein when the control unit performs the pre-jetting operation, the control unit controls the head unit and the head maintenance unit so that the liquid receiving block is located under the head and the decompression value is turned on when the head discharges the ink in the form of droplets.
